(19) United States
(12) Patent Application Publication
(10) Pub. No.: US 2023/0400526 A1
(43) Pub. Date: Dec. 14, 2023

(54) DIAGNOSIS METHOD OF BATTERY, DIAGNOSIS APPARATUS OF BATTERY, MANAGEMENT SYSTEM OF BATTERY, AND NON-TRANSITORY STORAGE MEDIUM

(71) Applicant: KABUSHIKI KAISHA TOSHIBA, Tokyo (JP)

(72) Inventors: Yuta KANAI, Yokohama (JP); Ryosuke YAGI, Yokohama (JP); Wataru UNO, Yokohama (JP); Norihiro YOSHINAGA, Yokohama (JP)

(73) Assignee: KABUSHIKI KAISHA TOSHIBA, Tokyo (JP)

(21) Appl. No.: 18/451,330

(22) Filed: Aug. 17, 2023

Related U.S. Application Data
(63) Continuation of application No. PCT/JP2021/043268, filed on Nov. 25, 2021.

(51) Int. Cl. G01R 31/389; H02J 7/00

(52) U.S. Cl. CPC G01R 31/389; H02J 7/0047

(57) ABSTRACT

In a diagnosis method of an embodiment, a battery, which includes, as electrode active materials, a first electrode active material whose impedance has a first natural frequency and a second natural frequency lower than the first natural frequency and a second electrode active material whose impedance has a third natural frequency with a magnitude between the first natural frequency and the second natural frequency, is diagnosed. In the method, an impedance of the battery is measured at each of a plurality of measurement target frequencies by setting, as a measurement range, a first measurement range including the first natural frequency and not including the second and third natural frequencies, and a second measurement range including the second natural frequency and not including the first and third natural frequencies.

### CROSS-REFERENCE TO RELATED APPLICATIONS

This is a Continuation Application of PCT Application No. PCT/JP2021/043268, filed Nov. 25, 2021, the entire contents of which are incorporated herein by reference.

### FIELD

Embodiments described herein relate generally to a diagnosis method of a battery, a diagnosis apparatus of the battery, a management system of the battery, and a non-transitory storage medium.

### BACKGROUND

In recent years, concerning a battery such as a secondary battery, the internal state of the battery is estimated based on measurement data including measured values of the current, the voltage, and the like of the battery, and degradation of the battery and the like are diagnosed based on the estimation result of the internal state and the like. In such determination, in the estimation of the internal state of the battery as a determination target, the capacity of a positive electrode as the capacity of a positive electrode active material in the battery, the capacity of a negative electrode as the capacity of a negative electrode active material in the battery, the resistance component of the impedance of the battery, and the like are estimated as internal state parameters representing the internal state of the battery. In the battery such as a secondary battery, when charging and discharging are repeated, the resistance component of the impedance of the battery as one of the internal state parameters changes, as compared to that at the start of use. Therefore, by estimating the resistance component of the impedance of the battery as the internal resistance of the battery, it is possible to diagnose degradation of the battery and the like.

One of methods of estimating the resistance component of the battery is, for example, an AC impedance method. In the AC impedance method, the impedance of the battery is measured at each of a plurality of measurement target frequencies by, for example, inputting an AC current to the battery at each of the plurality of measurement target frequencies, thereby measuring the frequency characteristic of the impedance of the battery. Then, fitting calculation is performed using the equivalent circuit of the battery set with a plurality of electric characteristic parameters (circuit constants) corresponding to the impedance components of the battery and the measurement result of the impedance of the battery at each of the measurement target frequencies, thereby calculating each of the electric characteristic parameters of the equivalent circuit. After that, the resistance component of the impedance of the battery is calculated based on the calculation results of the electric characteristic parameters, thereby calculating, for example, the charge transfer resistances of the positive electrode and the negative electrode.

If the resistance component of the impedance of the battery is estimated, as described above, it is required to decrease the number of measurement target frequencies at which the impedance of the battery is measured and to shorten the measurement time taken to measure the frequency characteristic of the impedance of the battery. Even if the number of measurement target frequencies is small, it is required to appropriately estimate the resistance component of the impedance and appropriately diagnose degradation of the battery and the like.

### BRIEF DESCRIPTION OF THE DRAWINGS

FIG. 1 is a schematic block diagram showing a management system of a battery according to the first embodiment.

FIG. 2 is a schematic diagram showing an example of a current flowing to the battery in measurement of the impedance of the battery according to the first embodiment.

FIG. 3 is a schematic diagram showing an example, different from FIG. 2, of the current flowing to the battery in measurement of the impedance of the battery according to the first embodiment.

FIG. 4 is a circuit diagram schematically showing an example of the equivalent circuit of the battery used for fitting calculation according to the first embodiment.

FIG. 5 is a schematic diagram showing examples of the measurement result of the impedance of the battery at each of measurement target frequencies and the frequency characteristic of the charge transfer impedance of each of a first electrode active material (first electrode) and a second electrode active material (second electrode) calculated based on the measurement result according to the first embodiment.

FIG. 6 is a flowchart schematically illustrating an example of processing in the diagnosis of the battery, which is performed by a diagnosis apparatus according to the first embodiment.

FIG. 7 is a flowchart schematically illustrating an example of processing of determining the measurement range of a frequency at which the impedance is measured, which is performed by an impedance measurement unit and the like of the diagnosis apparatus according to the first modification.

### DETAILED DESCRIPTION

According to an embodiment, a diagnosis method of a battery, which includes, as electrode active materials, a first electrode active material whose impedance has a first natural frequency and a second natural frequency lower than the first natural frequency and a second electrode active material whose impedance has a third natural frequency with a magnitude between a magnitude of the first natural frequency and a magnitude of the second natural frequency, is provided. In the method, an impedance of the battery is measured at each of a plurality of measurement target frequencies by setting, as a measurement range, a first measurement range including the first natural frequency and not including the second natural frequency and the third natural frequency, and a second measurement range including the second natural frequency and not including the first natural frequency and the third natural frequency. In the method, a state of the battery is determined based on a measurement result of the impedance of the battery at each of the measurement target frequencies.

### EMBODIMENTS

Embodiments will be described below with reference to the accompanying drawings.

### First Embodiment

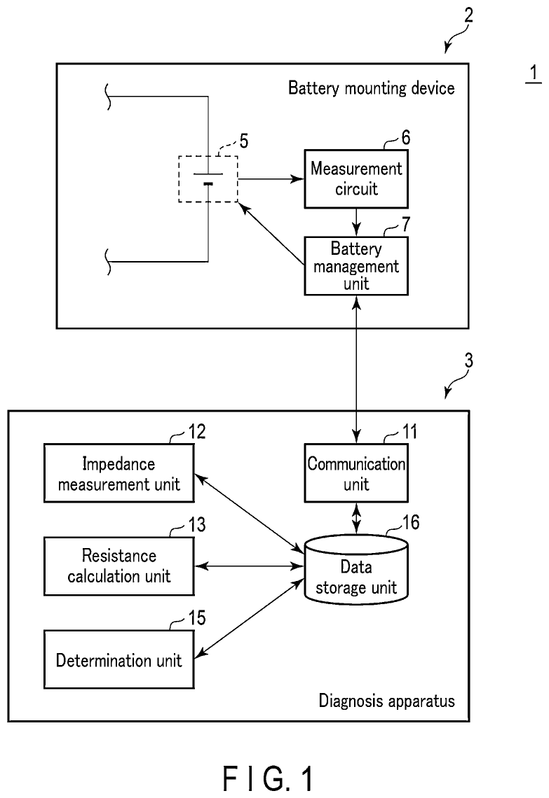

As an example of the embodiment, the first embodiment will be described first. FIG. 1 is a schematic block diagram showing a management system of a battery according to the first embodiment. As shown in FIG. 1, a management system 1 includes a battery mounting device 2 and a diagnosis apparatus 3. A battery 5, a measurement circuit 6, and a battery management unit (BMU) 7 are mounted in the battery mounting device 2. Examples of the battery mounting device 2 are a large power storage apparatus for an electric power system, a smartphone, a vehicle, a stationary power supply device, a robot, and a drone, and examples of a vehicle serving as the battery mounting device 2 are a railroad vehicle, an electric bus, an electric car, a plug-in hybrid car, and an electric motorcycle.

The battery 5 is, for example, a secondary battery such as a lithium ion secondary battery. The battery 5 may be formed by a unit cell (unit battery), or may be a battery module or a cell block formed by electrically connecting a plurality of unit cells. When the battery 5 is formed by a plurality of unit cells, the plurality of unit cells may electrically be connected in series, or may electrically be connected in parallel in the battery 5. In addition, both a series-connection structure in which a plurality of unit cells are connected in series and a parallel-connection structure in which a plurality of unit cells are connected in parallel may be formed in the battery 5. Furthermore, the battery 5 may be any one of a battery string, a battery array, and a storage battery, in each of which a plurality of battery modules are electrically connected.

In this embodiment, the battery 5 includes two kinds of electrode active materials. The impedance of a first electrode active material as one of the two kinds of electrode active materials has a natural frequency (first natural frequency) F1 and a natural frequency (second natural frequency) F2 lower than the natural frequency F1. The impedance of a second electrode active material different from the first electrode active material of the two kinds of electrode active materials has a natural frequency (third natural frequency) F3 with a magnitude between the magnitudes of the natural frequencies F1 and F2. Each of the natural frequencies F1 to F3 changes as at least one of the temperature of the battery 5 and the charging amount of the battery 5 changes. In an example, as long as the temperature, the charging amount, and the like of the battery 5 satisfy the use condition of the battery the ratio of the natural frequency F1 to the natural frequency F2 is 50 (inclusive) to 5,000 (inclusive). Then, as long as the temperature, the charging amount, and the like of the battery 5 satisfy the use condition of the battery 5, the ratio of the natural frequency F3 to the natural frequency F2 is 10 (inclusive) to 1,000 (inclusive).

In an example, the battery 5 is a lithium ion secondary battery that is charged and discharged as lithium ions move between a positive electrode and a negative electrode. The first electrode as one of the positive electrode and the negative electrode includes the first electrode active material as an electrode active material, and the first electrode active material performs a two-phase coexistence reaction in each of occlusion and release of lithium. The second electrode as one of the positive electrode and the negative electrode, which has a polarity opposite to that of the first electrode, includes the second electrode active material as an electrode active material, and the second electrode active material performs a single-phase reaction (solid solution reaction) in each of occlusion and release of lithium. As described above, an example of the lithium ion secondary battery with the first electrode including the first electrode active material that performs a two-phase coexistence reaction is a secondary battery with the negative electrode serving as the first electrode including lithium titanate as a negative electrode active material (first electrode active material). In this case, the positive electrode serving as the second electrode includes, for example, nickel cobalt manganese oxide as the positive electrode active material (second electrode active material) that performs a single-phase reaction. Furthermore, an example of the lithium ion secondary battery with the first electrode containing the first electrode active material that performs a two-phase coexistence reaction is a secondary battery with the positive electrode serving as the first electrode containing lithium iron phosphate as a positive electrode active material (first electrode active material). In this case, the negative electrode serving as the second electrode contains, for example, a carbonaceous material as the negative electrode active material (second electrode active material) that performs a single-phase reaction.

The measurement circuit 6 detects and measures parameters associated with the battery 5. The measurement circuit 6 periodically detects and measures the parameters at a predetermined timing. In a state in which the battery is charged or discharged, the measurement circuit 6 periodically measures the parameters associated with the battery 5. Even in a state where a signal for measurement such as a current or the like (to be described later) for which the impedance of the battery 5 is measured is input to the battery 5, the measurement circuit 6 periodically measures the parameters associated with the battery 5. The parameters associated with the battery 5 include a current flowing to the battery 5 and the voltage of the battery 5. Therefore, the measurement circuit 6 includes an ammeter that measures a current and a voltmeter that measures a voltage. The parameters associated with the battery 5 may include the temperature of the battery 5. In this case, the measurement circuit 6 includes a temperature sensor that measures a temperature.

The battery management unit 7 forms a processing apparatus (computer) for managing the battery 5 by, for example, controlling charging and discharging of the battery 5, and includes a processor and a storage medium (non-transitory storage medium). The processor includes one of a CPU (Central Processing Unit), an ASIC (Application Specific Integrated Circuit), a microcomputer, an FPGA (Field Programmable Gate Array), and a DSP (Digital Signal Processor). The storage medium can include an auxiliary storage device in addition to a main storage device such as a memory. As the storage medium, a magnetic disk, an optical disk (a CD-ROM, a CD-R, a DVD, or the like), a magnetooptical disk (an MO or the like), a semiconductor memory, or the like can be used. The battery management unit 7 may include only one processor and one storage medium, or may include a plurality of processors and a plurality of storage media. In the battery management unit 7, the processor performs processing by executing a program and the like stored in the storage medium. The program to be executed by the processor in the battery management unit 7 may be stored in a computer (server) connected via a network such as the Internet or a server in a cloud environment. In this case, the processor downloads the program via the network.

The diagnosis apparatus 3 diagnoses degradation of the battery 5 and the like. Therefore, the battery 5 is the diagnosis target of the diagnosis apparatus 3. In an example shown in FIG. 1 or the like, the diagnosis apparatus 3 is provided outside the battery mounting device 2. The diagnosis apparatus 3 includes a communication unit 11, an impedance measurement unit 12, a resistance calculation unit 13, a determination unit 15, and a data storage unit 16. The diagnosis apparatus 3 is, for example, a server that can communicate with the battery management unit 7 via the network. In this case, similar to the battery management unit 7, the diagnosis apparatus 3 includes a processor and a storage medium (non-transitory storage medium). Then, the communication unit 11, the impedance measurement unit 12, the resistance calculation unit 13, and the determination unit 15 execute some of processes performed by the processor of the diagnosis apparatus 3 and the like, and the storage medium of the diagnosis apparatus 3 functions as the data storage unit 16.

Note that in an example, the diagnosis apparatus 3 may be a cloud server formed in a cloud environment. The infrastructure of the cloud environment is formed by a virtual processor such as a virtual CPU and a cloud memory. Hence, if the diagnosis apparatus 3 is a cloud server, the communication unit 11, the impedance measurement unit 12, the resistance calculation unit 13, and the determination unit 15 execute some of processes performed by the virtual processor. The cloud memory functions as the data storage unit 16.

Note that the data storage unit 16 may be provided in a computer separated from the battery management unit 7 and the diagnosis apparatus 3. In this case, the diagnosis apparatus 3 is connected, via a network, to the computer in which the data storage unit 16 and the like are provided. Alternatively, the diagnosis apparatus 3 may be mounted in the battery mounting device 2. In this case, the diagnosis apparatus 3 is formed from a processing apparatus or the like mounted in the battery mounting device 2. If the diagnosis apparatus 3 is mounted in the battery mounting device 2, one processing apparatus or the like mounted in the battery mounting device 2 may perform processing of the battery management unit 7 such as control of charging and discharging of the battery 5 while performing processing (to be described later) of the diagnosis apparatus 3. The processing of the diagnosis apparatus 3 will be described below.

The communication unit 11 communicates with a processing apparatus other than the diagnosis apparatus 3 via the network. For example, the communication unit 11 receives, from the battery management unit 7, measurement data including the measurement results, by the measurement circuit 6, of the above-described parameters associated with the battery 5. The measurement data is generated by the battery management unit 7 and the like based on the measurement results by the measurement circuit 6. The measurement data includes the measured values of the parameters associated with the battery 5. If the parameters associated with the battery 5 are measured at each of a plurality of time points of measurement, the measurement data includes the measured values of the parameters associated with the battery 5 at each of the plurality of time points of measurement and time changes (time histories) of the parameters associated with the battery 5. Therefore, the measurement data includes the time change (time history) of the current of the battery 5 and the time change (time history) of the voltage of the battery 5, and may also include the time change (time history) of the temperature of the battery 5. The communication unit 11 writes the received measurement data in the data storage unit 16.

At least one of the processors of the battery management unit 7 and the diagnosis apparatus 3 may estimate one of the charging amount and the SOC of the battery 5 based on the measurement results, by the measurement circuit 6, of the parameters associated with the battery 5. Then, the diagnosis apparatus 3 may acquire, as data included in the above-described measurement data, the estimated value of the charging amount of the battery 5 and the time change (time history) of the estimated value of the charging amount of the battery 5. The charging amount of the battery 5 in real time can be calculated based on the charging amount of the battery 5 at a reference time point such as the start of use of the battery 5 and the time change of the current flowing to the battery 5 from the reference time point. In this case, the current integrated value of the current of the battery 5 from the reference time point is calculated based on the time change of the current. Then, the charging amount of the battery 5 in real time is calculated based on the charging amount of the battery 5 at the reference time point and the calculated current integrated value.

In the battery 5, for the voltage, a lower limit voltage Vmin and an upper limit voltage Vmax are defined. In the battery 5, a state in which the voltage in discharging or charging under a predetermined condition becomes the lower limit voltage Vmin is defined as a state in which the SOC is 0 (0%), and a state in which the voltage in discharging or charging under a predetermined condition becomes the upper limit voltage Vmax is defined as a state in which the SOC is 1 (100%). Furthermore, in the battery 5, a charging capacity until the SOC changes from 0 to 1 in charging under a predetermined condition or a discharging capacity until the SOC changes from 1 to 0 in discharging under a predetermined condition is defined as a battery capacity. The ratio of a remaining capacity until the state in which the SOC is 0 to the battery capacity of the battery is the SOC of the battery.

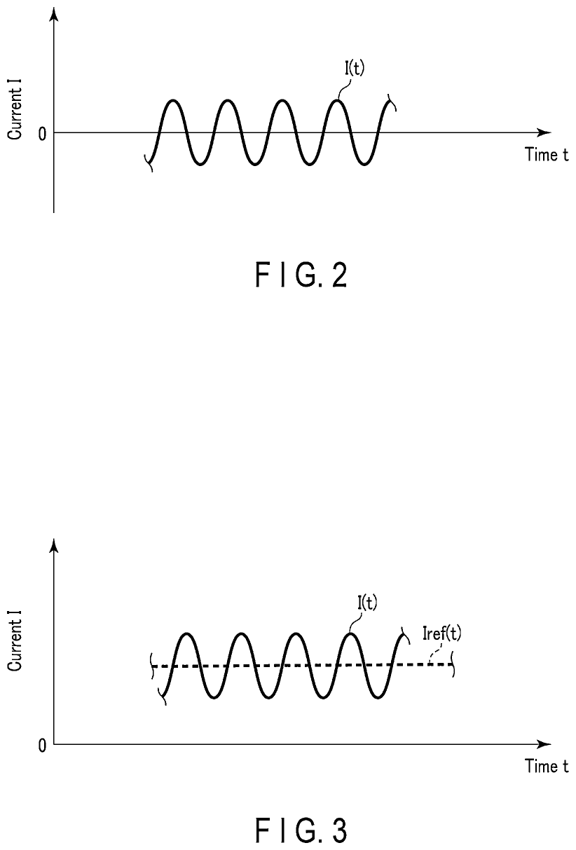

The impedance measurement unit 12 measures the impedance of the battery 5 as the determination target based on the measurement data and the like received by the communication unit 11. In measurement of the impedance of the battery 5 by the impedance measurement unit 12, the battery management unit 7 and the like cause a current with a current waveform with a periodically changing current value to flow to the battery 5. FIG. 2 is a graph showing an example of a current flowing to the battery in measurement of the impedance of the battery according to the first embodiment. FIG. 3 is a graph showing an example, different from FIG. 2, of the current flowing to the battery in measurement of the impedance of the battery according to the first embodiment. In FIGS. 2 and 3, the abscissa represents time t and the ordinate represents a current I.

In an example shown in FIG. 2, in measurement of the impedance of the battery 5, the battery management unit 7 and the like input, to the battery 5, an AC current with a current waveform I(t) with a periodically changing flowing direction. On the other hand, in an example shown in FIG. 3, a DC current with the current waveform I(t) with a current value that periodically changes with a reference current locus Iref(t) being as the center is input to the battery 5. The reference current locus Iref(t) is, for example, the locus of the time change of a charging current set as a charging condition for charging or the like of the battery 5. Therefore, in addition to the AC current, the current with the current waveform with the periodically changing current value includes the DC current with the current value that periodically changes with the reference current locus being as the center.

In an example, the impedance of the battery 5 is measured simultaneously with charging of the battery 5. In this case, a current with a current waveform with a current value that periodically changes with the reference current locus being as the center, which is set as the locus of the time change of the charging current, is input to the battery 5, thereby measuring the impedance of the battery 5. In the reference current locus in charging, the current value of the charging current may be constant over time, or the current value of the charging current may change with time. In addition, in each of the examples shown in FIGS. 2 and 3, the current waveform is a sinusoidal wave (sin wave) but the current waveform may be a current waveform such as a triangular wave or a sawtooth wave other than the sinusoidal wave.

In a state in which the current with the current waveform with the periodically changing current value is input to the battery 5, as described above, the measurement circuit 6 measures the current and the voltage of the battery 5 at each of the plurality of time points of measurement. The communication unit 11 of the diagnosis apparatus 3 receives, as the above-described measurement data, the measurement results of the current and the voltage of the battery 5 obtained in the state in which the current with the current waveform with the periodically changing current value is input to the battery 5. The measurement results of the current and the voltage of the battery 5 obtained in the state in which the current with the current waveform with the periodically changing current value is caused to flow to the battery 5 include the measured values of the current and the voltage of the battery 5 at each of the plurality of time points of measurement, and the time changes (time histories) of the current and the voltage of the battery 5.

In an example, the impedance measurement unit 12 calculates a peak-to-peak value (variation width) in the periodical change of the current of the battery 5 based on the time change of the current of the battery 5, and calculates a peak-to-peak value (variation width) in the periodical change of the voltage of the battery 5 based on the time change of the voltage of the battery 5. The impedance measurement unit 12 then calculates the impedance of the battery 5 from the ratio of the peak-to-peak value of the voltage to the peak-to-peak value of the current. Note that in another example, the impedance of the battery may be calculated from the ratio of the effective value of the voltage to the effective value of the current.

The impedance measurement unit 12 measures the impedance of the battery 5 at each of a plurality of frequencies. That is, the impedance measurement unit 12 sets a plurality of frequencies as measurement target frequencies, and measures the impedance of the battery 5 at each of the measurement target frequencies. In an example, the battery management unit 7 and the like input a current with the above-described current waveform to the battery 5 while changing the frequency among the plurality of measurement target frequencies. Then, the communication unit 11 of the diagnosis apparatus 3 receives, as the measurement data, the measurement results of the current and the voltage of the battery 5 in a state in which the current is input to the battery 5 at each of the plurality of measurement target frequencies. The impedance measurement unit 12 calculates the impedance of the battery 5 in the above-described way in the state in which the current is input to the battery 5 at each of the plurality of measurement target frequencies based on the measurement data. In this embodiment, by measuring the impedance of the battery 5 at each of the plurality of measurement target frequencies, the frequency characteristic of the impedance of the battery 5 is measured.

Furthermore, in this embodiment, a measurement range within which the impedance is measured includes a first measurement range and a second measurement range. The first measurement range includes the natural frequency F1 and does not include the natural frequencies F2 and F3. Then, the second measurement range includes the natural frequency F2 and does not include the natural frequencies F1 and F3. If the impedance is measured within each of the first measurement range and the second measurement range, the impedance may or may not be measured outside the first measurement range and the second measurement range.

In addition, under the condition that the measurement range includes the first measurement range and the second measurement range, the number of measurement target frequencies at which the impedance is measured is preferably as small as possible. In an example, the number of measurement target frequencies is set to a reference number or less, for example, 5 or less. In this case, the number of measurement target frequencies at which the impedance measurement unit 12 measures the impedance of the battery 5 is 2 (inclusive) to 5 (inclusive). The measurement target frequencies at which the impedance of the battery 5 is measured include any frequency within the above-described first measurement range and any frequency within the above-described second measurement range. In an example, the measurement target frequencies include the above-described natural frequencies F1 and F2 of the impedance of the first electrode active material. Furthermore, the measurement target frequencies may include a frequency outside the first measurement range and the second measurement range in addition to the natural frequencies F1 and F2 of the impedance of the first electrode active material. In an example, the measurement target frequencies may include the natural frequency F3 of the impedance of the second electrode active material in addition to the natural frequencies F1 and F2. However, in this embodiment, as long as the impedance of the battery 5 is measured for each of the first measurement range including the natural frequency F1 and the second measurement range including the natural frequency F2, the impedance of the battery 5 need not be measured at a frequency such as the natural frequency F3 outside the first measurement range and the second measurement range.

In this example, assume that the frequency of the above-described current waveform can be changed within a range of a frequency Fa (inclusive) to a frequency Fb (inclusive), and the above-described natural frequencies F1 to F3 fall within the range of the frequency Fa (inclusive) to the frequency Fb (inclusive). In an example, the impedance of the battery 5 is measured in ascending order of frequency at each of four measurement target frequencies including the frequency Fa, the natural frequency (second natural frequency) F2 included in the second measurement range, the natural frequency (first natural frequency) F1 included in the first measurement range, and the frequency Fb. In another example, the impedance of the battery 5 is measured in ascending order of frequency at each of five measurement target frequencies including the frequency Fa, the natural frequency (second natural frequency) F2, the natural frequency (third natural frequency) F3, the natural frequency (first natural frequency) F1, and the frequency Fb. In each of these examples, the number of measurement target frequencies at which the impedance of the battery 5 is measured is small, for example, 5 or less (the reference number or less). Then, in each of these examples, the measurement target frequencies include the natural frequencies F1 and F2 (the first measurement range and the second measurement range).

In measurement of the impedance of the battery 5 at each of the measurement target frequencies, it is not always necessary to input, to the battery 5, the current with the current waveform of the measurement target frequency. In an example, the measurement target frequencies include the natural frequencies F1 and F2. Then, in measurement of the impedance of the battery 5 at the natural frequency F1, a current with a current waveform of a frequency F1+ΔF slightly higher than the natural frequency F1 is input to the battery 5, and the impedance of the battery 5 is measured at the frequency F1+ΔF. Furthermore, a current with a current waveform of a frequency F1−ΔF slightly lower than the natural frequency F1 is input to the battery 5, and the impedance of the battery 5 is measured at the frequency F1−ΔF. Then, the impedance of the battery 5 at the natural frequency F1 is calculated based on the measurement results of the impedance at the frequencies F1+ΔF and F1−ΔF. Note that the impedance of the battery 5 at the natural frequency F2 may also be calculated based on the measurement results of the impedance of the battery 5 at a frequency F2+ΔF slightly higher than the natural frequency F2 and a frequency F2−ΔF slightly lower than the natural frequency F2.

The impedance measurement unit 12 acquires, for example, a complex impedance plot (Cole-Cole plot) of the impedance as the measurement result of the frequency characteristic of the impedance of the battery 5. In this embodiment, on the complex impedance plot, the impedance of the battery 5 is plotted for each of the plurality of measurement target frequencies at which the impedance is measured. Then, on the complex impedance plot, the real component and imaginary component of the impedance of the battery 5 are plotted for each of the plurality of measurement target frequencies. Note that the method of measuring the frequency characteristic of the impedance of the battery by inputting the current with the current waveform with the periodically changing current value to the battery, the complex impedance plot as the measurement result of the frequency characteristic of the impedance of the battery, and the like are described in reference literature 1 (Japanese Patent Laid-Open No. 2017-106889).

As described above, each of the natural frequencies F1 to F3 changes in accordance with a change of each of the temperature and charging amount of the battery 5. Therefore, in this embodiment, data representing the relationship between the natural frequency (first natural frequency) F1 of the impedance of the first electrode active material and each of the temperature, SOC, and charging amount of the battery 5 and data representing the relationship between the natural frequency (second natural frequency) F2 of the impedance of the first electrode active material and each of the temperature and charging amount of the battery 5 are stored in the data storage unit 16. In measurement of the impedance of the battery 5 at each of the measurement target frequencies, the impedance measurement unit 12 specifies the natural frequency F1 based on the real-time measurement results of the temperature and charging amount of the battery 5 and the data representing the relationship between the natural frequency F1 and each of the temperature and charging amount of the battery 5. Then, the impedance measurement unit 12 specifies the natural frequency F2 based on the real-time measurement results of the temperature and charging amount of the battery 5 and the data representing the relationship between the natural frequency F2 and each of the temperature and charging amount of the battery 5.

Note that the natural frequencies F1 and F2 may be specified using the SOC of the battery 5 instead of the charging amount. In this case, data representing the relationship between the natural frequency F1 and each of the temperature and SOC of the battery 5 and data representing the relationship between the natural frequency F2 and each of the temperature and SOC of the battery 5 are stored in the data storage unit 16.

Furthermore, in an example, the measurement target frequencies include the natural frequency (third natural frequency) F3 of the impedance of the second electrode active material in addition to the natural frequencies F1 and F2. In this case, data representing the relationship between the natural frequency F3 of the impedance of the second electrode active material and each of the temperature and charging amount of the battery 5 is stored in the data storage unit 16. Then, in measurement of the impedance of the battery 5 at each of the measurement target frequencies, the impedance measurement unit 12 specifies the natural frequencies F1 and F2 in the above-described way, and also specifies the natural frequency F3 based on the real-time measurement results of the temperature and charging amount of the battery 5 and the data representing the relationship between the natural frequency F3 and each of the temperature and charging amount of the battery 5. Note that the natural frequency F3 may be specified using the SOC of the battery 5 instead of the charging amount. In this case, the data representing the relationship between the natural frequency F3 and each of the temperature and SOC of the battery 5 is stored in the data storage unit 16.

In an example, the frequency characteristic of the impedance of the battery 5 is measured in the above-described way only in a state in which the temperature of the battery 5 becomes a predetermined temperature. In this case, data representing the relationship between each of the natural frequencies F1 to F3 and the charging amount or SOC of the battery 5 under the condition that the temperature of the battery 5 becomes the predetermined temperature is stored in the data storage unit 16. Then, the impedance measurement unit 12 specifies each of the natural frequencies F1 to F3 based on the real-time measurement result of the charging amount or SOC of the battery 5 and the data representing the relationship between each of the natural frequencies F1 to F3 and the charging amount or SOC of the battery 5. In another example, the frequency characteristic of the impedance of the battery 5 is measured only in a state in which the charging amount of the battery 5 becomes a predetermined charging amount or a state in which the SOC of the battery becomes a predetermined SOC. In this case, data representing the relationship between the temperature of the battery 5 and each of the natural frequencies F1 to F3 under the condition that the charging amount of the battery becomes the predetermined charging amount or the condition that the SOC of the battery 5 becomes the predetermined SOC is stored in the data storage unit 16. Then, the impedance measurement unit 12 specifies each of the natural frequencies F1 to F3 based on the real-time measurement result of the temperature of the battery 5 and the data representing the relationship between the temperature of the battery 5 and each of the natural frequencies F1 to F3.

In another example, the frequency characteristic of the impedance of the battery 5 is measured only in a state in which the charging amount of the battery 5 becomes the predetermined charging amount and the temperature of the battery 5 becomes the predetermined temperature. In this case, the natural frequencies F1 to F3 under the condition that the charging amount of the battery 5 becomes the predetermined charging amount and the temperature of the battery 5 becomes the predetermined temperature are stored in the data storage unit 16. Alternatively, the frequency characteristic of the impedance of the battery 5 may be measured only in a state in which the SOC of the battery 5 becomes the predetermined SOC and the temperature of the battery 5 becomes the predetermined temperature. In this case, the natural frequencies F1 to F3 under the condition that the SOC of the battery 5 becomes the predetermined SOC and the temperature of the battery 5 becomes the predetermined temperature are stored in the data storage unit 16.

In an example, experiment data acquired in an experiment using a half cell including only one of the positive electrode and the negative electrode is stored in the data storage unit 16 for each of the natural frequencies F1 to F3. As the half cell, a three-pole cell using one of the positive electrode and the negative electrode for the working electrode and metal lithium for the reference electrode and the counter electrode, or a bipolar cell using one of the positive electrode and the negative electrode for the working electrode and metal lithium for the counter electrode can be used, but the half cell is not limited to them. In this case, in the experiment using the half cell, the natural frequencies F1 to F3 are acquired under each of a plurality of conditions in which at least one of the temperature and charging amount (SOC) of the half cell is different. Note that unlike the battery 5 as the diagnosis target, information concerning the natural frequencies F1 to F3 is acquired using the half cell, and then, the impedance is measured at each of the plurality of measurement target frequencies in regard to the battery 5 as the diagnosis target in the above-described way. In any of the above-described examples, the impedance measurement unit 12 measures the impedance of the battery 5 at each of the plurality of measurement target frequencies by setting, as the measurement range, the first measurement range including the natural frequency F1 and the second measurement range including the natural frequency F2. The number of measurement target frequencies becomes small, for example, the reference number such as 5 or less. The impedance measurement unit 12 writes, in the data storage unit 16, the measurement result of the impedance of the battery 5 at each of the measurement target frequencies as the measurement result of the frequency characteristic of the impedance of the battery 5.

The resistance calculation unit 13 calculates the resistance component of the impedance of the battery 5 based on the measurement result of the frequency characteristic of the impedance of the battery 5, that is, the measurement result of the impedance of the battery 5 at each of the plurality of measurement target frequencies. The resistance calculation unit 13 calculates, for example, the charge transfer resistance of the first electrode active material and the charge transfer resistance of the second electrode active material as resistance components of the impedance. In the battery 5, the first electrode active material is used as the electrode active material of the first electrode, and the second electrode active material is used as the electrode active material of the second electrode having a polarity opposite to that of the first electrode. In this case, the resistance calculation unit 13 calculates the charge transfer resistance of the first electrode based on the charge transfer resistance of the first electrode active material, and calculates the charge transfer resistance of the second electrode based on the charge transfer resistance of the second electrode active material.

The impedance components of the battery 5 include the charge transfer impedances of the positive electrode and the negative electrode, and the resistance component of the charge transfer impedance is a charge transfer resistance in each of the positive electrode and the negative electrode. In each of the positive electrode and the negative electrode, the charge transfer resistance has a magnitude corresponding to the charge transfer resistance of the electrode active material. Note that the impedance components of the battery 5 include an ohmic resistance including a resistance in the moving process of lithium in an electrolyte or the like, a Warburg impedance including a diffusion resistance, and the inductance component of the battery 5 in addition to the charge transfer impedance. The resistance calculation unit 13 can calculate the impedance components of the battery 5 including the charge transfer resistances of the positive electrode and the negative electrode using the measurement result of the impedance of the battery 5 at each of the measurement target frequencies.

The data storage unit 16 stores an equivalent circuit model including information concerning the equivalent circuit of the battery 5. In the equivalent circuit of the equivalent circuit model, a plurality of electric characteristic parameters (circuit constants) corresponding to the impedance components of the battery 5 are set. The electric characteristic parameters are parameters representing the electric characteristic of a circuit element provided in the equivalent circuit. The electric characteristic parameters include a resistance, a capacitance (capacity), an inductance, and an impedance. If a CPE (Constant Phase Element) is used as the circuit element of the equivalent circuit instead of a capacitor, a capacitance and a Debye experience parameter are set as the electric characteristic parameters of the CPE. The plurality of electric characteristic parameters of the equivalent circuit include electric characteristic parameters corresponding to the impedance components of the natural frequency F3 as electric characteristic parameters corresponding to the charge transfer impedance of the second electrode active material. In addition, the plurality of electric characteristic parameters of the equivalent circuit may include electric characteristic parameters corresponding to the impedance components of the natural frequency F1 and electric characteristic parameters corresponding to the impedance components of the natural frequency F2 as electric characteristic parameters corresponding to the charge transfer impedance of the first electrode active material.

The equivalent circuit model stored in the data storage unit 16 includes data representing the relationship between the electric characteristic parameters of the equivalent circuit and the natural frequencies F1 to F3 and data representing the relationship between the electric characteristic parameters of the equivalent circuit and the impedance of the battery 5. The data representing the relationship between the electric characteristic parameters of the equivalent circuit and the natural frequencies F1 to F3 indicates, for example, an expression for calculating the natural frequency F1 from the electric characteristic parameters corresponding to the impedance components of the natural frequency F1, an expression for calculating the natural frequency F2 from the electric characteristic parameters corresponding to the impedance components of the natural frequency F2, and an expression for calculating the natural frequency F3 from the electric characteristic parameters corresponding to the impedance components of the natural frequency F3. The data representing the relationship between the electric characteristic parameters and the impedance of the battery 5 indicates, for example, an expression for calculating each of the real component and the imaginary component of the impedance from the electric characteristic parameters (circuit constants). In this case, in the expression, each of the real component and the imaginary component of the impedance of the battery is calculated using the electric characteristic parameters, the frequency, and the like.

The resistance calculation unit 13 performs fitting calculation using the equivalent circuit model including the equivalent circuit and the measurement result of the impedance of the battery 5 at each of the measurement target frequencies. At this time, the fitting calculation is performed using the electric characteristic parameters of the equivalent circuit as variables, thereby calculating the electric characteristic parameters as the variables. Furthermore, in the fitting calculation, for example, the values of the electric characteristic parameters as the variables are decided such that the difference between the calculation result of the impedance using the expression included in the equivalent circuit model and the measurement result of the impedance becomes as small as possible at each of the measurement target frequencies at which the impedance is measured. In the fitting calculation, a frequency at which the impedance is actually measured or a frequency specified based on the temperature, the charging amount, and the like of the battery is substituted as each of the natural frequencies F1 to F3, thereby performing calculation.

By performing the fitting calculation, as described above, the electric characteristic parameters corresponding to the impedance components of the natural frequencies F1 to F3 are calculated. The resistance calculation unit 13 calculates the frequency characteristic of the charge transfer impedance of the second electrode active material and the charge transfer resistance of the second electrode active material based on the calculation results of the electric characteristic parameters corresponding to the impedance components of the natural frequency F3. Furthermore, the resistance calculation unit 13 calculates the frequency characteristic of the charge transfer impedance of the first electrode active material and the charge transfer resistance of the first electrode active material based on the calculation results of the electric characteristic parameters corresponding to the impedance components of the natural frequency F1 and the calculation results of the electric characteristic parameters corresponding to the impedance components of the natural frequency F2. The frequency characteristic of the charge transfer impedance of each of the first electrode active material and the second electrode active material is shown on, for example, a Nyquist diagram such as a complex impedance plot (Cole-Cole plot).

In the battery 5, the first electrode includes the first electrode active material and the second electrode includes the second electrode active material. In this case, the resistance calculation unit 13 calculates the frequency characteristic of the charge transfer impedance of the first electrode, the charge transfer resistance of the first electrode, and the like based on the calculation results of the frequency characteristic of the charge transfer impedance of the first electrode active material and the charge transfer resistance of the first electrode active material. Then, the resistance calculation unit 13 calculates the frequency characteristic of the charge transfer impedance of the second electrode, the charge transfer resistance of the second electrode, and the like based on the calculation results of the frequency characteristic of the charge transfer impedance of the second electrode active material and the charge transfer resistance of the second electrode active material. The resistance calculation unit 13 writes, in the data storage unit 16, the calculation results of the resistance components of the impedance of the battery 5 including the calculation results of the charge transfer resistances of the first electrode active material and the second electrode active material, and the calculation results of the frequency characteristics of the impedance components of the battery 5 including the calculation results of the frequency characteristics of the charge transfer impedances of the first electrode active material and the second electrode active material. Note that the equivalent circuit and the like of the battery are described in reference literature 1. Furthermore, the method of calculating the electric characteristic parameters (circuit constants) of the equivalent circuit by performing the fitting calculation using the measurement result of the frequency characteristic of the impedance of the battery and the equivalent circuit model of the battery, and the like are described in reference literature 1.

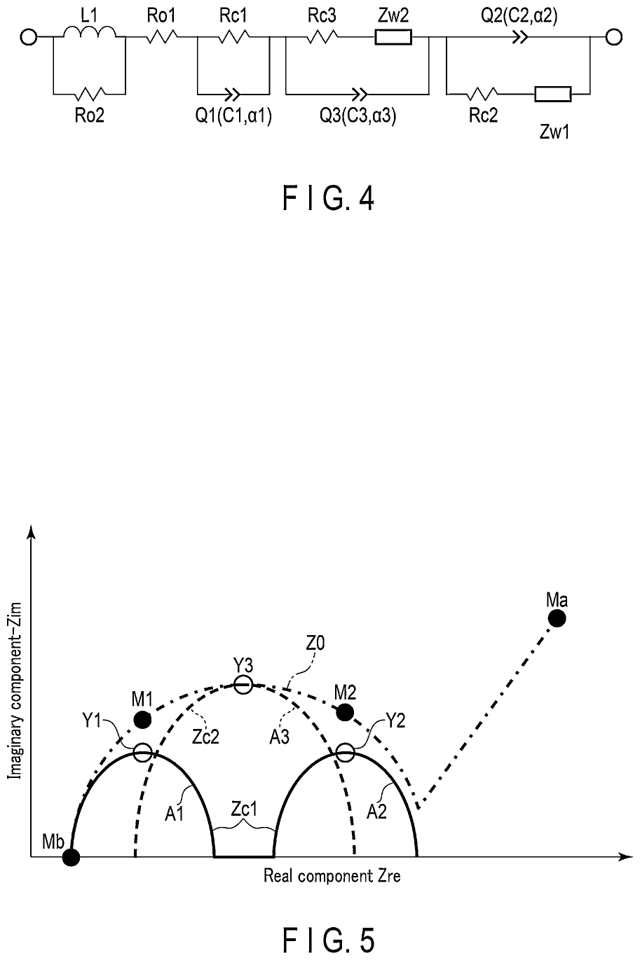

FIG. 4 is a circuit diagram schematically showing an example of the equivalent circuit of the battery used for the fitting calculation according to the first embodiment. In the equivalent circuit in the example shown in FIG. 4, resistances Ro1, Ro2, Rc1, Rc2, and Rc3, capacitances C1, C2, and C3, an inductance L1, impedances Zw1 and Zw2, and Debye experience parameters α1, α2, and α3 are set as the electric characteristic parameters corresponding to the impedance components of the battery 5. Here, the resistances Ro1 and Ro2 correspond to resistance components serving as ohmic resistances, the inductance L1 corresponds to the inductance component of the battery 5, and the impedances Zw1 and Zw2 correspond to impedance components serving as Warburg impedances.

When i=1, 2, 3 is set, a capacitance Ci and a Debye experience parameter αi are electric characteristic parameters of a CPE (Constant Phase Element) Qi. Then, a resistance Rci, the capacitance Ci, and the Debye experience parameter αi correspond to impedance components of the natural frequency Fi. In the equivalent circuit, the resistances Rc1 and Rc2, the capacitances C1 and C2, and the Debye experience parameters α1 and α2 correspond to impedance components serving as the charge transfer impedances of the first electrode active material, and the resistances Rc1 and Rc2 correspond to resistance components serving as charge transfer resistances of the first electrode active material. Then, in the equivalent circuit, the resistance Rc3, the capacitance C3, and the Debye experience parameter α3 correspond to impedance components serving as the charge transfer impedances of the second electrode active material, and the resistance Rc3 corresponds to a resistance component serving as the charge transfer resistance of the second electrode active material.

In a case where the equivalent circuit in the example shown in FIG. 4 is used for the fitting calculation, an expression for calculating each of the real component and the imaginary component of the impedance of the battery 5 using the electric characteristic parameters including the resistances Ro1, Ro2, Rc1, Rc2, and Rc3 and the capacitances C1, C2, and C3 is included in the data of the equivalent circuit model. Furthermore, an expression for calculating each of the natural frequencies F1 to F3 using one or more of the electric characteristic parameters including the resistances Ro1, Ro2, Rc1, Rc2, and Rc3 and the capacitances C1, C2, and C3 is included in the data of the equivalent circuit model. In an example, as an expression for calculating each of the natural frequencies Fi from the electric characteristic parameters of the equivalent circuit, equation (1) below is included in the data of the equivalent circuit model.

$$Fi = \frac{1}{2 {π ( Rci Ci )}^{1 / α i}} ( i = 1 , 2 , 3 ) \qquad ( 1 )$$

After that, the above-described fitting calculation is performed using the equivalent circuit model including information concerning the equivalent circuit in the example of FIG. 4 and the measurement result of the impedance of the battery 5 at each of the measurement target frequencies, thereby calculating the electric characteristic parameters of the equivalent circuit. In an example, the electric characteristic parameters such as the resistances Ro1, Ro2, Rc1, Rc2, and Rc3, the capacitances C1, C2, and C3, and the Debye experience parameters α1, α2, and α3 serving as variables in the fitting calculation are calculated.

If the electric characteristic parameters of the equivalent circuit are calculated by the fitting calculation, as described above, the sum of the resistances Rc1 and Rc2 is calculated as the charge transfer resistance of the first electrode active material. In addition, the resistance Rc3 is calculated as the charge transfer resistance of the second electrode active material. Assume that the first electrode contains only the first electrode active material as an electrode active material, and the second electrode contains only the second electrode active material as an electrode active material. In this case, the sum of the resistances Rc1 and Rc2 is calculated as the charge transfer resistance of the first electrode, and the resistance Rc3 is calculated as the charge transfer resistance of the second electrode.

In an example, the data of the equivalent circuit model includes an expression for calculating the charge transfer impedance of the first electrode active material using the resistances Rc1 and Rc2, the capacitances C1 and C2, the Debye experience parameters α1 and α2, the frequency, and the like, and an expression for calculating the charge transfer impedance of the second electrode active material using the resistance Rc3, the capacitance C3, the Debye experience parameter α3, the frequency, and the like. When the electric characteristic parameters of the equivalent circuit are calculated by the fitting calculation, the frequency characteristic of the charge transfer impedance of the first electrode active material is calculated by, for example, substituting the calculation results of the resistances Rc1 and Rc2, the capacitances C1 and C2, and the Debye experience parameters α1 and α2 into the above-described expression. Furthermore, the frequency characteristic of the charge transfer impedance of the second electrode active material is calculated by, for example, substituting the calculation results of the resistance Rc3, the capacitance C3, and the Debye experience parameter α3 into the above-described expression.

Assume that the first electrode contains only the first electrode active material as an electrode active material, and the second electrode contains only the second electrode active material as an electrode active material. In this case, the frequency characteristic of the charge transfer impedance of the first electrode active material is calculated as the frequency characteristic of the charge transfer impedance of the first electrode, and the frequency characteristic of the charge transfer impedance of the second electrode active material is calculated as the frequency characteristic of the charge transfer impedance of the second electrode. Note that for example, an impedance locus on the complex impedance plot is calculated as the frequency characteristic of the impedance of each of the first electrode active material (first electrode) and the second electrode active material (second electrode).

FIG. 5 is a graph showing examples of the measurement result of the impedance of the battery at each of the measurement target frequencies and the frequency characteristic of the charge transfer impedance of each of the first electrode active material (first electrode) and the second electrode active material (second electrode) calculated based on the measurement result according to the first embodiment. FIG. 5 shows a complex impedance plot, in which the abscissa represents a real component Zre of the impedance and the ordinate represents an imaginary component −Zim of the impedance. In an example shown in FIG. 5, the impedance of the battery 5 is measured in ascending order of frequency at each of four measurement target frequencies including a frequency Fa, the natural frequency (second natural frequency) F2 included in the second measurement range, the natural frequency (first natural frequency) F1 included in the first measurement range, and a frequency Fb. In FIG. 5, in regard to the impedance of the battery 5, a point Ma indicates the measurement result at the frequency Fa, a point M1 indicates the measurement result at the natural frequency F1, a point M2 indicates the measurement result at the natural frequency F2, and a point Mb indicates the measurement result at the frequency Fb. Furthermore, in FIG. 5, the points Ma, M1, M2, and Mb each indicating the measurement result of the impedance of the battery 5 are represented by filled circles.

In the example shown in FIG. 5, the frequency characteristic of the charge transfer impedance of each of the first electrode active material and the second electrode active material, which is calculated based on the measurement result of the impedance of the battery 5 and the above-described equivalent circuit is shown. On the complex impedance plot shown in FIG. 5, an impedance locus Zc1 is represented, by a solid line, as the frequency characteristic of the charge transfer impedance of the first electrode active material (first electrode), and an impedance locus Zc2 is represented, by a broken line, as the frequency characteristic of the charge transfer impedance of the second electrode active material (second electrode).

In the impedance locus Zc1 representing the frequency characteristic of the charge transfer impedance of the first electrode active material, arc portions A1 and A2 are shown. On the complex impedance plot, the arc portion A2 appears in a low frequency range, as compared with the arc portion A1. Furthermore, in the impedance locus Zc2 representing the frequency characteristic of the charge transfer impedance of the second electrode active material, an arc portion A3 is shown. On the complex impedance plot, the arc portion A3 appears in a low frequency range, as compared with the arc portion A1, and in a high frequency range, as compared with the arc portion A2.

When i=1, 2, 3 is set, a vertex Yi of an arc portion Ai is indicated by an open circle on the complex impedance plot shown in FIG. 5. A vertex Y1 indicates the calculation result of the charge transfer impedance of the first electrode active material (first electrode) at the natural frequency (first natural frequency) F1, and a vertex Y2 indicates the calculation result of the charge transfer impedance of the first electrode active material (first electrode) at the natural frequency (second natural frequency) F2. In addition, a vertex Y3 indicates the calculation result of the charge transfer impedance of the second electrode active material (second electrode) at the natural frequency (third natural frequency) F3. On the complex impedance plot shown in FIG. 5, an impedance locus ZO is represented, by a one-dot dashed line, as the frequency characteristic of the impedance of the battery 5. In deriving the impedance locus ZO, for example, the impedance locus ZO of the impedance of the battery 5 is calculated by, for example, substituting the values of the electric characteristic parameters calculated by the fitting calculation into the expression for calculating each of the real component and the imaginary component of the impedance of the battery 5 using the electric characteristic parameters, the frequency, and the like.

The determination unit 15 acquires the calculation results of the resistance components of the impedance of the battery 5, and acquires, for example, the calculation result of the charge transfer resistance of each of the first electrode active material (first electrode) and the second electrode active material (second electrode). Alternatively, the determination unit 15 may acquire the calculation result of the frequency characteristic of the charge transfer impedance of each of the first electrode active material (first electrode) and the second electrode active material (second electrode). In an example, the determination unit 15 determines degradation of the battery 5 based on the calculation result of the charge transfer resistance of each of the first electrode active material and the second electrode active material. In this case, as a change amount (increase amount) of the charge transfer resistance of the first electrode active material from the start of use of the battery 5 is larger, the degree of degradation of the battery 5 is determined to be higher, and as a change amount (increase amount) of the charge transfer resistance of the second electrode active material from the start of use of the battery 5 is larger, the degree of degradation of the battery 5 is determined to be higher.

The determination unit 15 determines the state of the battery 5 such as degradation of the battery 5 based on the calculation result of the frequency characteristic of the charge transfer impedance of each of the first electrode active material and the second electrode active material. In this case, as a change of the frequency characteristic of the charge transfer impedance of the first electrode active material from the start of use of the battery 5 is larger, the degree of degradation of the battery 5 is determined to be higher, and as a change of the frequency characteristic of the charge transfer impedance of the second electrode active material from the start of use of the battery 5 is larger, the degree of degradation of the battery 5 is determined to be higher. The determination unit 15 writes, in the data storage unit 16, the determination result of the state of the battery 5 including degradation of the battery 5.

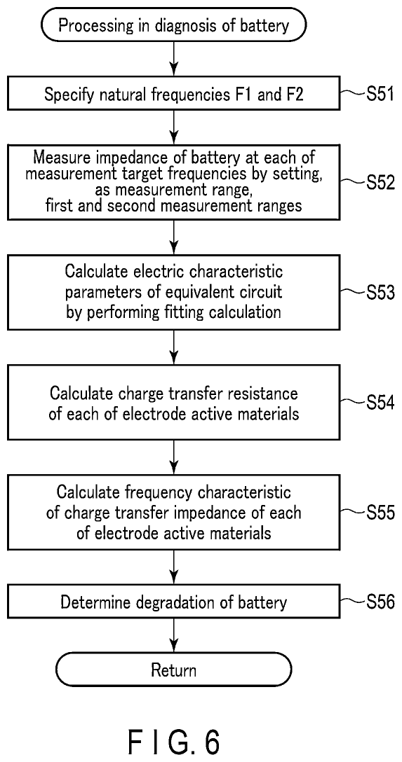

FIG. 6 is a flowchart schematically illustrating an example of processing in the diagnosis of the battery, which is performed by the diagnosis apparatus according to the first embodiment. When the processing shown in FIG. 6 is started, the impedance measurement unit 12 specifies the natural frequencies F1 and F2 of the first electrode active material based on the real-time measurement results of the temperature, the charging amount, and the like of the battery 5 in the above-described way (step S51). At this time, in addition to the natural frequencies F1 and F2, the impedance measurement unit 12 may specify the natural frequency F3 of the second electrode active material based on the temperature, the charge amount, and the like of the battery 5 in real time. Then, the impedance measurement unit 12 measures the impedance of the battery 5 at each of the plurality of measurement target frequencies, in the above-described way, by setting, as the measurement range, the first measurement range including the natural frequency F1 and the second measurement range including the natural frequency F2 (step S52). At this time, the plurality of measurement target frequencies may include a frequency outside the first measurement range and the second measurement range in addition to the frequency within the first measurement range and the frequency within the second measurement range. Then, the resistance calculation unit 13 calculates the electric characteristic parameters of the equivalent circuit by performing the fitting calculation using the measurement result of the impedance of the battery 5 at each of the measurement target frequencies and the equivalent model in the above-described way (step S53). At this time, the fitting calculation is performed using the electric characteristic parameters of the equivalent circuit as variables.

The resistance calculation unit 13 calculates the charge transfer resistance of each of the first electrode active material and the second electrode active material based on the electric characteristic parameters of the equivalent circuit (step S54). Furthermore, the resistance calculation unit 13 calculates the frequency characteristic of the charge transfer impedance of each of the first electrode active material and the second electrode active material based on the electric characteristic parameters of the equivalent circuit (step S55). Note that the resistance calculation unit 13 may calculate the charge transfer resistance of each of the first electrode and the second electrode and the frequency characteristic of the charge transfer impedance of each of the first electrode and the second electrode based on the electric characteristic parameters of the equivalent circuit. Then, the determination unit 15 determines degradation of the battery 5 and the like based on the calculation result of the charge transfer resistance of each of the first electrode active material and the second electrode active material and the calculation result of the frequency characteristic of the charge transfer impedance of each of the first electrode active material and the second electrode active material (step S56).

As described above, in this embodiment, in the battery 5, the impedance of the first electrode active material has the natural frequency F1 and the natural frequency F2 lower than the natural frequency F1, and the impedance of the second electrode active material has the natural frequency F3 with a magnitude between the magnitudes of the natural frequencies F1 and F2. In this battery 5, if the impedance of the battery 5 is measured within the first measurement range including the natural frequency F1 and not including the natural frequencies F2 and F3 and within the second measurement range including the natural frequency F2 and not including the natural frequencies F1 and F3, even if the number of measurement target frequencies at which the impedance of the battery 5 is measured is small, the resistance components of the impedance of the battery 5 and the like are calculated appropriately in the above-described way. Therefore, in this embodiment, the charge transfer resistance of each of the first electrode active material and the second electrode active material and the like are calculated appropriately while decreasing the number of measurement target frequencies at which the impedance of the battery 5 is measured, thereby appropriately diagnosing degradation of the battery 5 and the like.

In this embodiment, the number of measurement target frequencies at which the impedance of the battery 5 is measured becomes small, for example, the reference number such as 5 or less. Therefore, the measurement time taken to measure the frequency characteristic of the impedance of the battery 5 becomes short. This can shorten the time taken to diagnose degradation of the battery 5 and the like. When the measurement time of the frequency characteristic of the impedance of the battery 5 and the diagnosis time for the battery 5 are shortened, complication of a system configuration for measuring the frequency characteristic of the impedance of the battery 5, a system configuration for diagnosing degradation and the like of the battery 5, and the like is suppressed. In addition, it is possible to reduce cost and the like required to measure the frequency characteristic of the impedance of the battery 5 and diagnose the battery 5.

Furthermore, in this embodiment, even if the impedance of the battery 5 is not measured at the natural frequency F3, when the above-described fitting calculation is performed using the measurement result of the impedance of the battery 5 at each of the natural frequencies F1 and F2 (the first measurement range and the second measurement range), the electric characteristic parameters of the equivalent circuit corresponding to the impedance components of the third natural frequency are appropriately calculated. Therefore, even if the impedance of the battery is not measured at the natural frequency F3, it is possible to appropriately calculate the charge transfer resistance of the second electrode active material whose impedance has the natural frequency F3, and appropriately calculate the frequency characteristic of the charge transfer impedance of the second electrode active material. Therefore, in this embodiment, even if the impedance of the battery 5 is not measured at the natural frequency F3 of the impedance of the second electrode active material, the resistance components of the impedance of the battery 5 such as the charge transfer resistance of each of the first electrode active material and the second electrode active material are appropriately calculated, thereby appropriately determining degradation of the battery 5 and the like.

### Modification

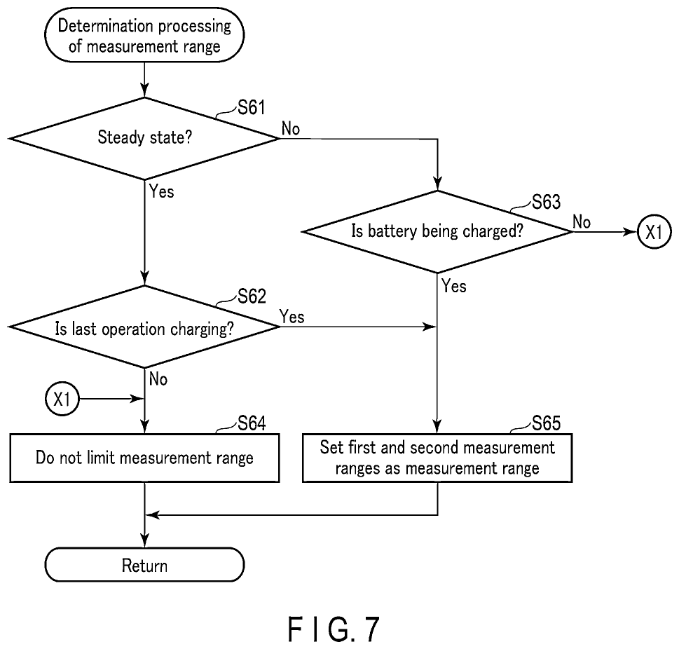

In the first modification of the above-described embodiment, the impedance measurement unit 12 of the diagnosis apparatus 3 determines, based on the operation state, the use state (use history), and the like of the battery 5, a measurement range within which the impedance of the battery 5 is measured. FIG. 7 is a flowchart schematically illustrating an example of determination processing of the measurement range, which is performed by the impedance measurement unit and the like of the diagnosis apparatus according to the first modification. The processing shown in FIG. 7 is executed, for example, immediately before degradation of the battery 5 and the like are diagnosed.

When the processing shown in FIG. 7 is started, the impedance measurement unit 12 determines whether the battery 5 is in a steady state in which the battery 5 is not operating (step S61). That is, it is determined whether the battery 5 is being charged or discharged. If the battery 5 is in the steady state (YES in step S61), that is, if the battery 5 is not being charged or discharged, the impedance measurement unit 12 determines whether the last operation of the battery 5 is charging (step S62). Whether the last operation of the battery 5 is charging can be determined based on the time change or the like of the charging amount of the battery 5. If the last operation of the battery 5 is not charging (NO in step S62), that is, if the last operation of the battery 5 is discharging, the impedance measurement unit 12 does not limit the measurement range (step S64). On the other hand, if the last operation of the battery 5 is charging (YES in step S62), the impedance measurement unit 12 sets, as the measurement range, the above-described first measurement range including the natural frequency F1 and the above-described second measurement range including the natural frequency F2 (step S65).

Alternatively, if the battery 5 is not in the steady state (NO in step S61), that is, if the battery 5 is operating, the impedance measurement unit 12 determines whether the battery 5 is being charged (step S63). Whether the battery 5 is being charged can be determined based on the time change or the like of the charging amount of the battery 5. If the battery 5 is not being charged (NO in step S63), that is, if the battery 5 is being discharged, the impedance measurement unit 12 does not limit the measurement range (step S64). On the other hand, if the battery 5 is being charged (YES in step S63), the impedance measurement unit 12 sets the first measurement range and the second measurement range as the measurement range (step S65). When the processing shown in FIG. 7 or the like is performed, in this modification, in each of a case where the battery 5 is being charged and a case where the last operation of the battery 5 that is not operating is charging, the impedance of the battery 5 is measured at each of the plurality of measurement target frequencies by setting the first measurement range and the second measurement range as the measurement range. By setting the first measurement range and the second measurement range as the measurement range, the number of measurement target frequencies at which the impedance of the battery 5 is measured is decided to be the reference number such as 5 or less, thereby decreasing the number of measurement target frequencies.

If the first measurement range and the second measurement range are decided as the measurement range in step S65 or the like, the impedance measurement unit 12 measures the impedance of the battery 5 at each of the plurality of measurement target frequencies by setting the first measurement range and the second measurement range as the measurement range, similar to the above-described embodiment or the like. Then, the resistance components of the impedance of the battery 5 such as the charge transfer resistance of each of the first electrode active material and the second electrode active material are calculated, similar to the above-described embodiment or the like, using the measurement result of the impedance of the battery 5 at each of the measurement target frequencies, thereby determining degradation of the battery 5 and the like.

If the measurement range is not limited in step S64 or the like, the impedance measurement unit 12 measures the impedance of the battery 5 at each of a number of measurement target frequencies, and for example, the number of measurement target frequencies is larger than the reference number. In this case as well, the electric characteristic parameters of the equivalent circuit are calculated by performing the fitting calculation using the measurement result of the impedance of the battery 5 at each of the measurement target frequencies, the above-described equivalent circuit model, and the like, thereby calculating the resistance components of the impedance of the battery 5 and the like. Then, degradation of the battery 5 and the like are determined based on the calculation results of the resistance components of the impedance of the battery 5 and the like. In an example, if it is decided not to limit the measurement range, the impedance of the battery 5 is measured at each of measurement target frequencies which include the natural frequencies F1 to F3 and the number of which is three times or more of the reference number.

In this example, assume that in the battery 5, lithium titanate is used as the first electrode active material and lithium titanate is used as the electrode active material of the negative electrode serving as the first electrode. In this battery 5, during charging, the impedance locus representing the frequency characteristic of the charge transfer impedance of lithium titanate tends to be readily separated into the above-described two arc portions A1 and A2, and the above-described two natural frequencies F1 and F2 tend to readily appear in the frequency characteristic of the impedance of lithium titanate. On the other hand, during discharging, the impedance locus representing the frequency characteristic of the charge transfer impedance of lithium titanate tends to be hardly separated into the two arc portions A1 and A2, and the two natural frequencies F1 and F2 tend to hardly appear in the frequency characteristic of the impedance of lithium titanate.

Furthermore, in the steady state in which the battery 5 is not operating, if the last operation of the battery is charging, the impedance locus representing the frequency characteristic of the charge transfer impedance of lithium titanate tends to be readily separated into the two arc portions A1 and A2, and the two natural frequencies F1 and F2 tend to readily appear in the frequency characteristic of the impedance of lithium titanate. On the other hand, even in the steady state of the battery 5, if the last operation of the battery is discharging, the impedance locus representing the frequency characteristic of the charge transfer impedance of lithium titanate tends to be hardly separated into the two arc portions A1 and A2, and the two natural frequencies F1 and F2 tend to hardly appear in the frequency characteristic of the impedance of lithium titanate.

Because of the above-described tendencies, in the battery 5 using lithium titanate as the first electrode active material, the measurement range within which the impedance of the battery 5 is measured is decided by the processing shown in the example of FIG. 6 or the like, thereby deciding the measurement range, within which the impedance of the battery 5 is measured, to be a range within which the resistance components of the impedance of the battery 5 and the like can appropriately be calculated. That is, in accordance with the operation state, the use state (use history), and the like of the battery 5, the measurement range within which the impedance of the battery is measured is decided to be a range within which degradation of the battery 5 and the like can appropriately be determined.

In a modification, in each of a case where the battery 5 is being discharged and a case where the last operation of the battery 5 that is not operating is discharging, it is unnecessary to measure the frequency characteristic of the impedance of the battery 5 or diagnose degradation of the battery 5 and the like. In this modification as well, in each of a case where the battery 5 is being charged and a case where the last operation of the battery 5 that is not operating is charging, the above-described first measurement range and second measurement range are decided as the measurement range within which the impedance of the battery 5 is measured. Then, the impedance of the battery 5 is measured at each of the plurality of measurement target frequencies by setting, as the measurement range, the first measurement range including the natural frequency F1 and the second measurement range including the natural frequency F2, and calculation of the resistance components of the impedance of the battery 5 and determination of degradation of the battery 5 and the like are performed based on the measurement result of the impedance of the battery 5 at each of the measurement target frequencies.

Note that some modifications have been described and the same operation and effect as in the above-described embodiment or the like are obtained in each of the modifications. That is, in each of the modifications as well, it is possible to shorten the measurement time taken to measure the frequency characteristic of the impedance of the battery 5, and degradation of the battery 5 is appropriately diagnosed.

### Verification Associated with Embodiment

In addition, the following verification was conducted as a verification associated with the above-described embodiment and the like.

### REFERENCE EXAMPLE

In a reference example, concerning a battery (secondary battery) as a unit cell (unit battery), the frequency characteristic of an impedance was measured and the resistance components of the impedance were calculated, thereby performing diagnosis. In a battery as a diagnosis target, lithium titanate was used as an electrode active material of a negative electrode serving as a first electrode, and nickel cobalt manganese oxide was used as an electrode active material of a positive electrode serving as a second electrode. Therefore, the battery as the diagnosis target included lithium titanate as a first electrode active material, and nickel cobalt manganese oxide as a second electrode active material. In the battery, an electrode group including the positive electrode and the negative electrode was accommodated in an exterior portion formed from a laminate film. Furthermore, the battery capacity of the battery as the diagnosis target was 1.5 Ah.

The frequency characteristic of the impedance of the battery was measured by the AC impedance method. At this time, an AC current was input to the battery while changing the frequency of a current waveform within a range of 0.05 Hz (inclusive) to 3,000 Hz (inclusive). Then, as described above in the embodiment or the like, the impedance of the battery 5 was measured at each of a plurality of measurement target frequencies. In the reference example, the impedance of the battery 5 was measured at each of a number of measurement target frequencies. Furthermore, if a reference number was set to in the reference example, the number of measurement target frequencies was set to a number that was three times or more of the reference number, and the impedance of the battery was measured at each of the measurement target frequencies the number of which was 15 or more. If, as described in the embodiment or the like, a first measurement range and a second measurement range were defined, in the reference example, the first measurement range and the second measurement range were included in a measurement range within which the impedance was measured.

Furthermore, in measurement of the frequency characteristic of the impedance of the battery, the temperature, the charging amount, and the like of the battery were adjusted to a state in which the impedance of lithium titanate as the first electrode active material had two natural frequencies of 1,000 Hz and 0.55 Hz, and the impedance of nickel cobalt manganese oxide as the second electrode active material had a natural frequency of 13.7 Hz. Therefore, in the reference example, the frequency characteristic of the impedance of the battery was measured in a state in which 1,000 Hz corresponded to the natural frequency (first natural frequency) F1, 0.55 Hz corresponded to the natural frequency (second natural frequency) F2, and 13.7 Hz corresponded to the natural frequency (third natural frequency) F3. In addition, the measurement target frequencies at which the impedance of the battery was measured included 0.05 Hz, 0.55 Hz, 13.7 Hz, 1,000 Hz, and 3,000 Hz. Then, each of the measurement target frequencies was decided such that the measurement target frequencies were at equal intervals in a logarithmic scale (log 10 scale). In the reference example, a measurement time taken to measure the frequency characteristic of the impedance of the battery in the above-described way was calculated.

In the reference example, by performing fitting calculation using the measurement result of the impedance of the battery at each of the measurement target frequencies and the above-described equivalent circuit model, the electric characteristic parameters of the equivalent circuit were calculated. Then, based on the calculation results of the electric characteristic parameters of the equivalent circuit, the charge transfer resistance of lithium titanate as the first electrode active material, that is, the charge transfer resistance of the negative electrode serving as the first electrode was calculated. Furthermore, based on the calculation results of the electric characteristic parameters of the equivalent circuit, the charge transfer resistance of nickel cobalt manganese oxide as the second electrode active material, that is, the charge transfer resistance of the positive electrode serving as the second electrode was calculated. Then, the ratio between the charge transfer resistance of the negative electrode and that of the positive electrode was calculated.

### Example 1

In Example 1 as well, concerning a battery having the same configuration as in the reference example, the frequency characteristic of the impedance of the battery was measured. In Example 1 as well, in measurement of the frequency characteristic of the impedance of the battery, the temperature, the charging amount, and the like of the battery were adjusted to a state in which the impedances of lithium titanate and nickel cobalt manganese oxide respectively had the same natural frequencies as in the reference example. However, in Example 1, only five frequencies of 0.05 Hz, 0.55 Hz, 13.7 Hz, 1,000 Hz, and 3,000 Hz were set as measurement target frequencies at which the impedance of the battery was measured, and the number of measurement target frequencies was not larger than a reference number (5). Since the measurement target frequencies were decided, as described above, the measurement target frequencies at which the impedance of the battery was measured included the two natural frequencies (F1 and F2) of the impedance of lithium titanate as a first electrode active material and the natural frequency (F3) of the impedance of nickel cobalt manganese oxide as a second electrode active material. As described above, in Example 1, the impedance of the battery was measured by setting, as a measurement range, a first measurement range including the natural frequency F1 which is 1,000 Hz and a second measurement range including the natural frequency F2 which is 0.55 Hz.

In Example 1 as well, similar to the reference example, the measurement time taken to measure the frequency characteristic of the impedance of the battery was calculated. Furthermore, in Example 1 as well, similar to the reference example, the charge transfer resistance of a negative electrode serving as a first electrode and the charge transfer resistance of a positive electrode serving as a second electrode were calculated. Then, the ratio between the charge transfer resistance of the negative electrode and that of the positive electrode was calculated.

### Example 2

In Example 2 as well, concerning a battery having the same configuration as in the reference example, the frequency characteristic of the impedance of the battery was measured. In Example 2 as well, in measurement of the frequency characteristic of the impedance of the battery, the temperature, the charging amount, and the like of the battery were adjusted to a state in which the impedances of lithium titanate and nickel cobalt manganese oxide respectively had the same natural frequencies as in the reference example. However, in Example 2, only four frequencies of 0.05 Hz, 0.55 Hz, 1,000 Hz, and 3,000 Hz were set as measurement target frequencies at which the impedance of the battery was measured, and the number of measurement target frequencies was not larger than a reference number (5). Since the measurement target frequencies were decided, as described above, the measurement target frequencies at which the impedance of the battery was measured included the two natural frequencies (F1 and F2) of the impedance of lithium titanate as a first electrode active material. However, the natural frequency (F3) of the impedance of nickel cobalt manganese oxide as a second electrode active material was not included in the measurement target frequencies. As described above, in Example 2 as well, the impedance of the battery was measured by setting, as a measurement range, a first measurement range including the natural frequency F1 which is 1,000 Hz and a second measurement range including the natural frequency F2 which is 0.55 Hz.

In Example 2 as well, similar to the reference example, the measurement time taken to measure the frequency characteristic of the impedance of the battery was calculated. Furthermore, in Example 2 as well, similar to the reference example, the charge transfer resistance of a negative electrode serving as a first electrode and the charge transfer resistance of a positive electrode serving as a second electrode were calculated. Then, the ratio between the charge transfer resistance of the negative electrode and that of the positive electrode was calculated.

### Comparative Example 1

In Comparative Example 1 as well, concerning a battery having the same configuration as in the reference example, the frequency characteristic of the impedance of the battery was measured. In Comparative Example 1 as well, in measurement of the frequency characteristic of the impedance of the battery, the temperature, the charging amount, and the like of the battery were adjusted to a state in which the impedances of lithium titanate and nickel cobalt manganese oxide respectively had the same natural frequencies as in the reference example. However, in Comparative Example 1, only four frequencies of 0.05 Hz, Hz, 13.7 Hz, and 3,000 Hz were set as measurement target frequencies at which the impedance of the battery was measured, and the number of measurement target frequencies was not larger than a reference number (5). Since the measurement target frequencies were decided, as described above, the measurement target frequencies at which the impedance of the battery was measured included a lower one (F2) of the two natural frequencies (F1 and F2) of the impedance of lithium titanate as a first electrode active material, and the natural frequency (F3) of the impedance of nickel cobalt manganese oxide as a second electrode active material. However, a higher one (F1) of the two natural frequencies (F1 and F2) of the impedance of lithium titanate was not included in the measurement target frequencies. As described above, in Comparative Example 1, the impedance of the battery was measured by setting, as a measurement range, a second measurement range including the natural frequency F2 which is 0.55 Hz without setting, as the measurement range, a first measurement range including the natural frequency F1 which is 1,000 Hz.

In Comparative Example 1 as well, similar to the reference example, the measurement time taken to measure the frequency characteristic of the impedance of the battery was calculated. Furthermore, in Comparative Example 1 as well, similar to the reference example, the charge transfer resistance of a negative electrode serving as a first electrode and the charge transfer resistance of a positive electrode serving as a second electrode were calculated. Then, the ratio between the charge transfer resistance of the negative electrode and that of the positive electrode was calculated.

### Comparative Example 2

In Comparative Example 2 as well, concerning a battery having the same configuration as in the reference example, the frequency characteristic of the impedance of the battery was measured. In Comparative Example 2 as well, in measurement of the frequency characteristic of the impedance of the battery, the temperature, the charging amount, and the like of the battery were adjusted to a state in which the impedances of lithium titanate and nickel cobalt manganese oxide respectively had the same natural frequencies as in the reference example. However, in Comparative Example 2, only four frequencies of 0.05 Hz, 13.7 Hz, 1,000 Hz, and 3,000 Hz were set as measurement target frequencies at which the impedance of the battery was measured, and the number of measurement target frequencies was not larger than a reference number (5). Since the measurement target frequencies were decided, as described above, the measurement target frequencies at which the impedance of the battery was measured included a higher one (F1) of the two natural frequencies (F1 and F2) of the impedance of lithium titanate as a first electrode active material, and the natural frequency (F3) of the impedance of nickel cobalt manganese oxide as a second electrode active material. However, a lower one (F2) of the two natural frequencies (F1 and F2) of the impedance of lithium titanate was not included in the measurement target frequencies. As described above, in Comparative Example 2, the impedance of the battery was measured by setting, as a measurement range, a first measurement range including the natural frequency F1 which is 1,000 Hz without setting, as the measurement range, a second measurement range including the natural frequency F2 which is 0.55 Hz.

In Comparative Example 2 as well, similar to the reference example, the measurement time taken to measure the frequency characteristic of the impedance of the battery was calculated. Furthermore, in Comparative Example 2 as well, similar to the reference example, the charge transfer resistance of a negative electrode serving as a first electrode and the charge transfer resistance of a positive electrode serving as a second electrode were calculated. Then, the ratio between the charge transfer resistance of the negative electrode and that of the positive electrode was calculated.

### VERIFICATION RESULT AND CONSIDERATION

The measurement time for the frequency characteristic of the impedance of the battery was 150 s in the reference example, 31 s in Example 1, 29 s in Example 2, 29 s in Comparative Example 1, and 25 s in Comparative Example 2. Therefore, it was verified that the measurement time taken to measure the frequency characteristic of the impedance of the battery was shortened by decreasing the number of measurement target frequencies (measurement points) by, for example, setting the number of measurement target frequencies, at which the impedance of the battery was measured, to be equal to or smaller than the reference number.

Furthermore, the ratio between the charge transfer resistance of the negative electrode (first electrode) and that of the positive electrode (second electrode) was 40:60 in the reference example, 33:67 in Example 1, 45:55 in Example 2, 65:35 in Comparative Example 1, and 20:80 in Comparative Example 2. Therefore, in regard to the ratio between the charge transfer resistance of the negative electrode and that of the positive electrode, the difference between the calculation result in the reference example and that in each of Examples 1 and 2 was smaller than the difference between the calculation result in the reference example and that in each of Comparative Examples 1 and 2. That is, in each of Examples 1 and 2, the charge transfer resistance of each of the negative electrode and the positive electrode was calculated with high accuracy, and the resistance components of the impedance of the battery were estimated with high accuracy, as compared with Comparative Examples 1 and 2.

Therefore, it was verified that even if the number of measurement target frequencies was decreased, the resistance components of the impedance of the battery were appropriately estimated with high accuracy by including the two natural frequencies of the impedance of lithium titanate in the measurement target frequencies and estimating the resistance components of the battery using the measurement result of the impedance of the battery at each of the measurement target frequencies. That is, it was verified that even if the number of measurement target frequencies was decreased, the resistance components of the impedance of the battery were appropriately estimated with high accuracy by measuring the impedance by setting, as the measurement range, the first measurement range including the natural frequency F1 and the second measurement range including the natural frequency F2. Then, it was verified that in a case where at least one of the two natural frequencies of the impedance of lithium titanate was not included in the measurement target frequencies, if the number of measurement target frequencies was decreased, the accuracy of estimation of the resistance components of the impedance of the battery was decreased. That is, it was verified that in a case where the impedance was measured by not setting at least one of the first measurement range and the second measurement range as the measurement range, if the number of measurement target frequencies was decreased, the accuracy of estimation of the resistance components of the impedance of the battery was decreased.

In the at least one embodiment or example described above, the battery including, as electrode active materials, the first electrode active material whose impedance has the first natural frequency and the second natural frequency lower than the first natural frequency and the second electrode active material whose impedance has the third natural frequency with a magnitude between the magnitude of the first natural frequency and that of the second natural frequency is diagnosed. By setting, as the measurement range, the first measurement range including the first natural frequency and not including the second natural frequency and the third natural frequency, and the second measurement range including the second natural frequency and not including the first natural frequency and the third natural frequency, the impedance of the battery is measured at each of the plurality of measurement target frequencies. Then, based on the measurement result of the impedance of the battery at each of the measurement target frequencies, the state of the battery is determined. This can provide a diagnosis method of a battery, a diagnosis apparatus of the battery, a management system of the battery, and a diagnosis program of the battery which shorten the measurement time taken to measure the frequency characteristic of the impedance of the battery, and appropriately diagnose degradation of the battery.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A diagnosis method of a battery including, as electrode active materials, a first electrode active material whose impedance has a first natural frequency and a second natural frequency lower than the first natural frequency and a second electrode active material whose impedance has a third natural frequency with a magnitude between a magnitude of the first natural frequency and a magnitude of the second natural frequency, the method comprising:
measuring an impedance of the battery at each of a plurality of measurement target frequencies by setting, as a measurement range, a first measurement range including the first natural frequency and not including the second natural frequency and the third natural frequency, and a second measurement range including the second natural frequency and not including the first natural frequency and the third natural frequency; and
determining a state of the battery based on a measurement result of the impedance of the battery at each of the measurement target frequencies.

2. The diagnosis method according to claim 1, wherein
in the determining the state of the battery,
a frequency characteristic of a charge transfer impedance of the second electrode active material and a charge transfer resistance of the second electrode active material are calculated based on the measurement result of the impedance of the battery at each of the measurement target frequencies.

3. The diagnosis method according to claim 2, wherein
in the calculating the frequency characteristic of the charge transfer impedance of the second electrode active material and the charge transfer resistance of the second electrode active material,
by performing fitting calculation using an equivalent circuit set with a plurality of electric characteristic parameters including electric characteristic parameters corresponding to impedance components of the third natural frequency and the measurement result of the impedance of the battery at each of the measurement target frequencies, each of the electric characteristic parameters of the equivalent circuit is calculated, and
the frequency characteristic of the charge transfer impedance of the second electrode active material and the charge transfer resistance of the second electrode active material are calculated based on calculation results of the electric characteristic parameters corresponding to the impedance components of the third natural frequency.

4. The diagnosis method according to claim 1, wherein
in the determining the state of the battery,
a frequency characteristic of a charge transfer impedance of the first electrode active material and a charge transfer resistance of the first electrode active material are calculated based on the measurement result of the impedance of the battery at each of the measurement target frequencies.

5. The diagnosis method according to claim 4, wherein
in the calculating the frequency characteristic of the charge transfer impedance of the first electrode active material and the charge transfer resistance of the first electrode active material,
by performing fitting calculation using an equivalent circuit set with a plurality of electric characteristic parameters including electric characteristic parameters corresponding to impedance components of the first natural frequency and electric characteristic parameters corresponding to impedance components of the second natural frequency, and the measurement result of the impedance of the battery at each of the measurement target frequencies, the electric characteristic parameters of the equivalent circuit are calculated, and
the frequency characteristic of the charge transfer impedance of the first electrode active material and the charge transfer resistance of the first electrode active material are calculated based on calculation results of the electric characteristic parameters corresponding to the impedance components of the first natural frequency and the second natural frequency.

6. The diagnosis method according to claim 1, further comprising specifying the first natural frequency and the second natural frequency of the impedance of the first electrode active material based on at least one of a charging amount, an SOC, and a temperature of the battery.

7. The diagnosis method according to claim 1, further comprising:
determining, in a state where the battery is operating, whether the battery is being charged, and determining, in a state where the battery is not operating, whether a last operation of the battery is charging; and
measuring, in each of a case where the battery is being charged and a case where the last operation of the battery is the charging, the impedance of the battery at each of the measurement target frequencies by setting the first measurement range and the second measurement range as the measurement range.

8. A diagnosis apparatus of a battery including, as electrode active materials, a first electrode active material whose impedance has a first natural frequency and a second natural frequency lower than the first natural frequency and a second electrode active material whose impedance has a third natural frequency with a magnitude between a magnitude of the first natural frequency and a magnitude of the second natural frequency, the apparatus comprising:
a processor configured to
measure an impedance of the battery at each of a plurality of measurement target frequencies by setting, as a measurement range, a first measurement range including the first natural frequency and not including the second natural frequency and the third natural frequency, and a second measurement range including the second natural frequency and not including the first natural frequency and the third natural frequency, and
determine a state of the battery based on a measurement result of the impedance of the battery at each of the measurement target frequencies.

9. A management system of a battery, comprising:
a diagnosis apparatus defined in claim 8; and
the battery diagnosed by the diagnosis apparatus.

10. The management system according to claim 9, wherein in the battery, a ratio of the first natural frequency of the impedance of the first electrode active material to the second natural frequency of the impedance of the first electrode active material is not less than 50 to not more than 5,000.

11. The management system according to claim 9, wherein in the battery, a ratio of the third natural frequency of the impedance of the second electrode active material to the second natural frequency of the impedance of the first electrode active material is not less than 10 to not more than 1,000.

12. The management system according to claim 9, wherein
the first electrode active material is an electrode active material that performs a two-phase coexistence reaction, and
the second electrode active material is an electrode active material that performs a single-phase reaction.

13. The management system according to claim 12, wherein the first electrode active material is one of lithium titanate and lithium iron phosphate.

14. The management system according to claim 9, wherein the battery includes
a first electrode including the first electrode active material as an electrode active material, and
a second electrode having a polarity opposite to a polarity of the first electrode and including the second electrode active material as an electrode active material.

15. A non-transitory storage medium storing a diagnosis program of a battery, the battery including, as electrode active materials, a first electrode active material whose impedance has a first natural frequency and a second natural frequency lower than the first natural frequency and a second electrode active material whose impedance has a third natural frequency with a magnitude between a magnitude of the first natural frequency and a magnitude of the second natural frequency, the diagnosis program causing a computer to:
measure an impedance of the battery at each of a plurality of measurement target frequencies by setting, as a measurement range, a first measurement range including the first natural frequency and not including the second natural frequency and the third natural frequency, and a second measurement range including the second natural frequency and not including the first natural frequency and the third natural frequency; and
determine a state of the battery based on a measurement result of the impedance of the battery at each of the measurement target frequencies.
